(19) United States
(12) Patent Application Publication
(10) Pub. No.: US 2004/0075179 A1
(43) Pub. Date: Apr. 22, 2004

(54) Structural design of alignment mark

(75) Inventors: George Liu, Taoyuan Hsien (TW); Benjamin Szu-Min Lin, Hsinchu (TW)

Correspondence Address: J C PATENTS, INC., 4 VENTURE, SUITE 250, IRVINE, CA, 92618, US

(73) Assignee: UNITED MICROELECTRONICS CORP, HSINCHU (TW)

(21) Appl. No.: 10/065,977

(22) Filed: Dec. 5, 2002

(30) Foreign Application Priority Data
Oct. 22, 2002 (TW) 91124308

(51) Int. Cl. G03F 9/00; H01L 23/544

(52) U.S. Cl. 257/797

(57) ABSTRACT

A structural design for an alignment mark on a substrate having a plurality of layers thereon. The alignment mark is formed within a first dielectric layer above the substrate and a patterned metallic layer is formed within a second dielectric layer underneath the first dielectric layer. The patterned metallic layer includes a group of longitudinal metallic lines separated from each other by a distance smaller than the wavelength of light used in the aligning operation.

### CROSS REFERENCE TO RELATED APPLICATIONS

This application claims the priority benefit of Taiwan application serial no. 91124308, filed on Oct. 22, 2002.

### BACKGROUND OF THE INVENTION

1. Field of Invention

The present invention relates to a structural design of an alignment mark. More particularly, the present invention relates to an alignment mark having a patterned metallic layer underneath for reflecting the alignment beam and providing a better alignment accuracy.

2. Description of Related Art

Photolithography is a major process in the fabrication of semiconductor devices. As semiconductor devices are miniaturized and the level of integration is increased, processes such as photo-exposure and etching are increasingly difficult to execute and involve a greater number of steps. In particular, for a photolithographic process, any inappropriate pattern transfer may require a rework of the photoresist layer or, at worst, reduce an entire batch of wafer to scrap. Hence, to ensure the pattern on a photomask is accurately transferred to a wafer, the wafer must be accurately aligned before conducting a photoresist exposure.

In a conventional photo-exposure operation, alignment involves aligning the photomask with an alignment mark on a wafer where semiconductor devices are fabricated. The alignment mark includes two principle types, a zero mark and a floating non-zero mark. Both types of alignment marks utilize the formation of a scattering site or a diffraction edge caused by the presence of a step height during alignment. When a light source shines on the wafer, the diffraction pattern due to light projected onto the alignment mark may reflect back to an alignment sensor or a first order diffraction interferometer alignment system. Ultimately, the alignment accuracy is gauged.

The non-zero alignment mark is a planarized dielectric layer above the semiconductor substrate that provides necessary alignment when the zero alignment mark on the substrate loses its alignment function. The non-zero alignment mark is a plurality of closely spaced openings on a planarized dielectric layer above the semiconductor substrate. The openings contain metallic material deposited while conductive or metallic plugs are fabricated. Since the metallic material is opaque while the silicon dioxide dielectric layer is transparent, alternation between the metallic material and the dielectric layer forms a reticle pattern that facilitates alignment.

FIG. 1 is a schematic cross-sectional view showing the structural design of a conventional non-zero alignment mark. As shown in FIG. 1, the semiconductor substrate 100 has dielectric layers 102 and 104. Alignment marks 106 are buried within the dielectric layer 104. The number of dielectric layers within the dielectric stack 102 depends on the type of semiconductor device fabricated. In general, more than one dielectric layer is used. During alignment, a beam of light 108 is emitted from a sensor (not shown) and reflected back to the sensor so that the alignment between the photomask and the wafer is gauged.

However, the aforementioned structure includes a backing dielectric layer 102 underneath the alignment marks 106. Hence, the incoming beam 108 penetrating the alignment marks 106 may pass through the dielectric layer to reach the substrate 100. Some of the light may be reflected from the substrate 100 to form a reflection beam. Therefore, the thickness of the dielectric layer 102 has considerable effect on the optical path of the passing beam. In general, a thicker dielectric layer 102 leads to a less stable optical path and a deterioration of alignment accuracy.

To reduce inaccuracy, the introduction of a metallic platform within the dielectric layer underneath the alignment marks 106 is suggested. The metallic platform serves as a plane that reflects most of the incoming light back with less diffusion. However, a continuous metallic platform may cause dishing during chemical-mechanical polishing. When dishing occurs, the central portion of the metallic platform caves downwards so that the optical path of a reflecting beam is distorted. Ultimately, stability of the alignment is also compromised.

### SUMMARY OF INVENTION

Accordingly, one object of the present invention is to provide a structural design for an alignment mark capable of reducing the effect of thickness of a dielectric layer on the optical path of an align beam so that alignment accuracy is improved.

A second object of this invention is to provide a structural design for an alignment mark capable of providing a stable optical path for an align beam to travel.

To achieve these and other advantages and in accordance with the purpose of the invention, as embodied and broadly described herein, the invention provides a structural design for an alignment mark. The design is applied to a substrate having a plurality of structural layers thereon. The alignment mark is formed within the first dielectric layer above a substrate. A patterned metallic layer is formed within another dielectric layer below the first dielectric layer. The patterned metallic layer contains a plurality of parallel metallic lines with each metallic line separated from its neighbor by a pitch smaller that the wavelength of the alignment beam.

According to this invention, a patterned metallic layer is formed underneath the alignment marks. By forming, underneath the alignment marks, a plurality of metallic lines separated from each other by a pitch smaller than the wavelength of the sensing beam, an incoming align beam gets reflected from the patterned metallic layer without going to the dielectric layer below. Since the optical path is not affected by the thickness of the underlying dielectric layer, alignment accuracy between the photomask and the wafer is increased.

Furthermore, the patterned metallic layer comprises a plurality of slightly separated metallic lines. Hence, there is very little dishing after a chemical-mechanical polishing operation. Because a planar surface is formed after chemical-mechanical polishing, a stable optical path for the incoming aligning beam is provided.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view showing the structural design of a conventional non-zero alignment mark;

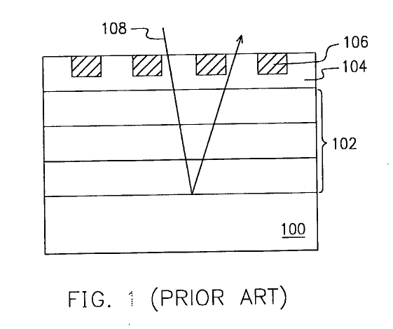

FIG. 2 is a perspective view showing various structural components constituting a non-zero alignment mark according to one preferred embodiment of this invention; and

FIG. 3 is a schematic cross-sectional view showing the structural design of a non-zero alignment mark according to this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

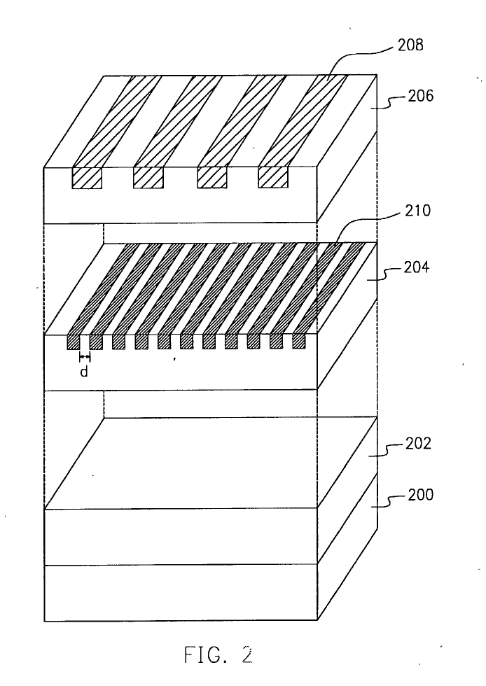

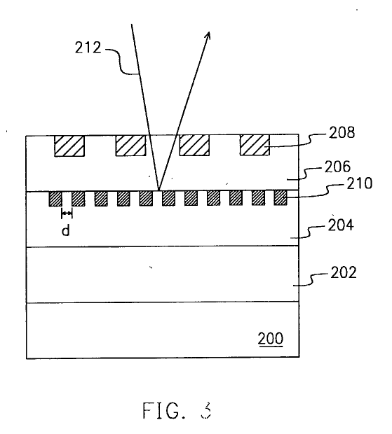

FIG. 2 is a perspective view showing various structural components constituting a non-zero alignment mark according to one preferred embodiment of this invention. FIG. 3 is a schematic cross-sectional view showing the structural design of a non-zero alignment mark according to this invention.

As shown in FIGS. 2 and 3, the alignment marks are formed within a planarized dielectric layer 206 above a semiconductor substrate 200. The alignment marks are formed, for example, by etching out a group of longitudinal openings (not shown) in the dielectric layer 206 and depositing the openings with a metallic material. In general, the alignment marks and other metallic lines of semiconductor devices are fabricated together so that identical metallic material such as aluminum, tungsten or copper is used in both processes.

Since the alignment marks 208 are made from opaque metallic material while the silicon dioxide dielectric layer 206 is transparent, the alternately positioned alignment marks 208 and dielectric layers 206 provides a reticle-like function suitable for alignment.

A patterned metallic layer 210 is formed within another dielectric layer 204. The dielectric layer 204 is underneath the dielectric layer 206. The patterned metallic layer 210 is a group of parallel longitudinal metallic lines having a direction of extension identical to the alignment marks 208 within the dielectric layer 206. The patterned metallic layer 210 is formed in a way similar to the alignment marks 208. The method includes forming a plurality of parallel longitudinal openings (not shown) in the dielectric layer 204 and depositing metallic material into the longitudinal openings. Similarly, the patterned metallic layer and other metallic lines of semiconductor devices are fabricated together so that identical metallic material such as aluminum, tungsten or copper can be used in both processes.

The longitudinal metallic lines within the patterned metallic layer 210 are separated from each other by a distance d. The distance d is set to a value smaller than the wavelength of the beam used for alignment. Currently, red light from a helium-neon (He—Ne) laser having a wavelength of 632.8 nm is often used for alignment. Hence, pitch d between neighboring metallic lines must be smaller than the wavelength of a helium-neon laser. The reason for setting the pitch d to a value smaller than the wavelength of a He—Ne laser is that a He—Ne laser beam 212 that passes through the dielectric layer 206 between the alignment marks 208 is reflected back from the patterned metallic layer 210. In this way, the patterned metallic layer 210 limits the optical path distortion to the thickness a single dielectric layer (the dielectric layer 206).

In addition, the patterned metallic layer 210 comprises a plurality of closely packed parallel metallic lines. Thus, the patterned metallic layer 210 will not dish after a chemical-mechanical polishing operation. Since the patterned metallic layer 210 is able to maintain a rather constant degree of planarity, an incoming beam for assessing the alignment will follow a stable optical path rather than reflecting in different directions due to a non-planar metallic layer surface.

Because the helium-neon laser has a wavelength of 632.8 nm or about 0.6 m, the patterned metallic layer 210 can have a certain high degree of manufacturing tolerance. As long as the patterned metallic layer 210 covers up the area occupied by the alignment marks 208 and the pitch between the metallic lines is smaller than the helium-neon laser wavelength, a stable optical path for reflecting back an incoming alignment beam is secured. Consequently, alignment accuracy is improved.

Furthermore, a helium-neon laser is used as an aligning beam in the aforementioned embodiment so that pitch between neighboring metal lines within the patterned metallic layer must be smaller than the laser wavelength. However, the only limiting condition is that the pitch between metallic lines should be smaller than the wavelength of the aligning beam selected.

Although the alignment marks and patterned metallic layer in the aforementioned embodiment are fabricated together with other metallic lines, the alignment marks and patterned metallic layer may also form in association with a via or dual damascene process.

In conclusion, this invention provides a patterned metallic layer underneath an alignment mark layer. Through a plurality of parallel metallic lines separated from each other by a small distance and by choosing a distance smaller than the wavelength of an incoming aligning beam, the incoming beam will be reflected back without going further into the dielectric layers below. Hence, optical path variation due to channeling the beam through a series of dielectric layers is reduced considerably and alignment accuracy between a photomask and a wafer is greatly improved.

Furthermore, the patterned metallic layer comprises a plurality of slightly separated metallic lines. Hence, there is very little dishing after a chemical-mechanical polishing operation. Because a planar surface is formed after chemical-mechanical polishing, a stable optical path for the incoming aligning beam is provided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A structural design for an alignment mark above a substrate having a plurality of layers thereon, comprising:a first dielectric layer over the substrate; a patterned metallic layer within a second dielectric layer, wherein the patterned metallic layer is constructed from an assembly of longitudinal metallic lines each separated from its neighbor by a distance smaller than the wavelength of a beam of aligning light used for the alignment; a third dielectric layer above the second dielectric layer and the patterned metallic layer; and an alignment mark within the third dielectric layer.

2. The design of claim 1, wherein the alignment mark is above the patterned metallic layer.

3. The design of claim 1, wherein the alignment mark includes a plurality of metallic lines alternating with the third dielectric layer.

4. The design of claim 3, wherein the longitudinal metallic lines within the patterned metallic layer are parallel to each other and extend in a direction parallel to the alignment mark.

5. The design of claim 1, wherein material forming the alignment mark is selected from a group consisting of aluminum, tungsten and copper.

6. The design of claim 1, wherein material forming the patterned metallic layer is selected from a group consisting of aluminum, tungsten and copper.

7. The design of claim 1, wherein the aligning beam includes a helium-neon laser beam.

8. A structural design for an alignment mark that facilitates alignment with an aligning beam, comprising:an alignment mark within a first dielectric layer; and a plurality of first metallic lines within a second dielectric layer, wherein the first metallic lines are underneath the alignment mark and extend over an area that entirely covers the alignment mark, and the separation between neighboring metallic lines is smaller than the wavelength of the aligning beam.

9. The design of claim 8, wherein the alignment mark further includes a plurality of second metallic lines that alternates with the first dielectric layer.

10. The design of claim 9, wherein the first metallic lines are parallel to each other and extend in a direction parallel to the alignment mark.

11. The design of claim 8, wherein material forming the alignment mark is selected from a group consisting of aluminum, tungsten and copper.

12. The design of claim 8, wherein material forming the first metallic lines is selected from a group consisting of aluminum, tungsten and copper.

13. The design of claim 8, wherein the aligning beam includes a helium-neon laser beam.
